(19) United States
(12) Patent Application Publication
(10) Pub. No.: US 2007/0205752 A1
(43) Pub. Date: Sep. 6, 2007

(54) Portable Electronics Testing Device

(76) Inventor: Dwayne Lamont Leigh, New London, NC (US)

Correspondence Address: ADVANTIA LAW GROUP, 9035 SOUTH 1300 EAST, SUITE 200, SANDY, UT, 84094, US

(21) Appl. No.: 11/307,716

(22) Filed: Feb. 17, 2006

(51) Int. Cl. G01R 31/28

(52) U.S. Cl. 324/158.1

(57) ABSTRACT

A portable electronics testing device for use in testing automotive electronics. There is a housing, including: a shell; a handle; and a wheel. There is an electronics module coupled to the housing, configured to test an electronic device, and including: a speaker module configured to produce audio; a speaker connection module coupled to the speaker module and configured to provide an interface for driving the speaker module; a power module configured to provide electrical power; and a receiver module configured to receive radio frequency information.

### BACKGROUND OF THE INVENTION

1. Field of the Invention

The present invention relates to portable electronics testing devices, specifically portable electronics testing devices for automotive electronics.

2. Description of the Related Art

In the field of consumer electronics, it is desired that systems be modular. Accordingly, components may often be interchanged and/or replaced as desired. Many times a system, such as a car audio system, may be altered, added to, or sold and other systems may integrate one or more parts from such a system. Installation of these components requires time and expertise. Further, as electronic components are generally fragile, they may be damaged during removal, installation, transportation, and/or storage. Accordingly, there is a need for portable testing of electronic components.

An example is illustrated by U.S. Pat. No. 4,670,709 to Iredale, which discloses a portable battery powered tone source with a built-in audio cable tester. Plural outputs consist of −40 dB, mic level; −10 dB line level and 1 W speaker level. Continuity in the system under test from input to speakers causes an audio frequency signal to be present at speakers. This systems own speakers can be used as monitors in the testing process. Moving the device (source) enables the user to audibly locate the point at which the continuity starts/stops. At such time the user can test the audio castle at that point. The various plugs of the device are compatible with all common audio jacks enabling the user to test all types of audio equipment as well as all types of audio cables with only one device. The device can also be used to test any direct point-to-point connection such as common ground or a PC board run with a simple test lead adaptor.

Also, U.S. Pat. No. 6,318,713 to Levi discloses a portable workbench, comprises a molded plastic base structure and a molded plastic upper work structure. Wheels and a transport handle are mounted on the base structure. The transport handle is constructed and arranged to be manually engaged to move the base structure between a) a storage operative position wherein the base structure is stabily supported on a horizontal surface and b) a storage transport position wherein the wheels rollingly contact the horizontal surface so that the base structure can be moved along the horizontal surface using the handle. The upper work structure is constructed and arranged to be supported on an upper portion of the base structure in a storage operative position. The upper work structure and the base structure cooperate when in the storage operative positions thereof to define a storage space. Releasable securing structure movable between a) a securing position wherein the upper work structure is fixedly secured to the base structure in the storage operative position thereof and b) a released position wherein the upper work structure can be moved with respect to the base structure from the storage operative position to allow access to the storage space is provided. The upper work structure defines a generally horizontal work surface when in the storage operative position thereof, the surface being constructed and arranged to support a workpiece. The upper work structure also embodies therein a clamping assembly for clamping a workpiece in fixed relation with respect to the work surface. An optional support structure is provided to mount the upper work structure in vertically spaced relatively above the base structure to raise the level of the work surface and of the clamping assembly for convenience.

What is needed is a portable electronics tester that solves one or more of the problems described herein and/or one or more problems that may come to the attention of one skilled in the art upon becoming familiar with this specification.

### SUMMARY OF THE INVENTION

The present invention has been developed in response to the present state of the art, and in particular, in response to the problems and needs in the art that have not yet been fully solved by currently available electronics testing devices. Accordingly, the present invention has been developed to provide a portable electronics testing device.

In one embodiment, there is a portable electronics testing device for use in testing automotive electronics. The portable electronics testing device may include a housing and an electronics module. The housing may include shell; a handle, coupled to the shell, configured to facilitate lifting the housing; and a wheel coupled to the shell and configured to facilitate travel of the housing. The electronics module may be coupled to the housing, configured to test an electronic device, and/or may include: a speaker module configured to produce audio; a speaker connection module coupled to the speaker module and/or configured to provide an interface for driving the speaker module; a power module configured to provide electrical power; and/or a receiver module configured to receive radio frequency information.

It may be that the speaker module comprises a set of four speakers each speaker independently interfaceable through the speaker connection module. Also, it may be that the housing further comprises an extendable handle. More, it may be that the housing further comprises a wire color code label.

Reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussion of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize that the invention can be practiced without one or more of the specific features or advantages of a particular embodiment. In other instances, additional features and advantages may be recognized in certain embodiments that may not be present in all embodiments of the invention.

These features and advantages of the present invention will become more fully apparent from the following description and appended claims, or may be learned by the practice of the invention as set forth hereinafter.

### BRIEF DESCRIPTION OF THE DRAWINGS

In order for the advantages of the invention to be readily understood, a more particular description of the invention briefly described above will be rendered by reference to specific embodiments that are illustrated in the appended drawings. Understanding that these drawings depict only typical embodiments of the invention and are not therefore to be considered to be limiting of its scope, the invention will be described and explained with additional specificity and detail through the use of the accompanying drawings, in which:

FIG. 1 illustrates a front plan view of a portable electronics testing device according to one embodiment of the invention; and

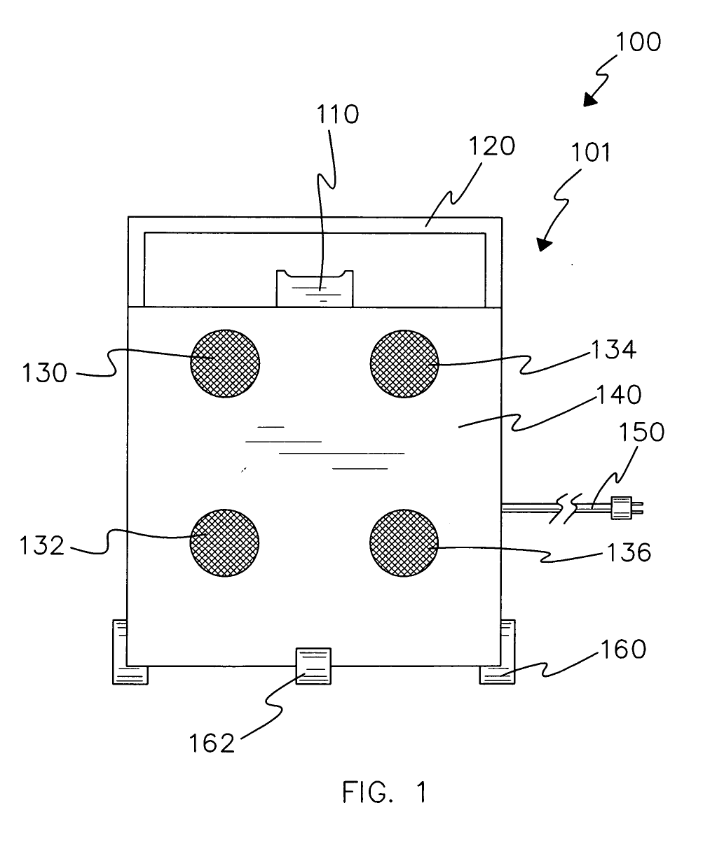

FIG. 2 illustrates a top plan view of a portable electronics testing device according to one embodiment of the invention.

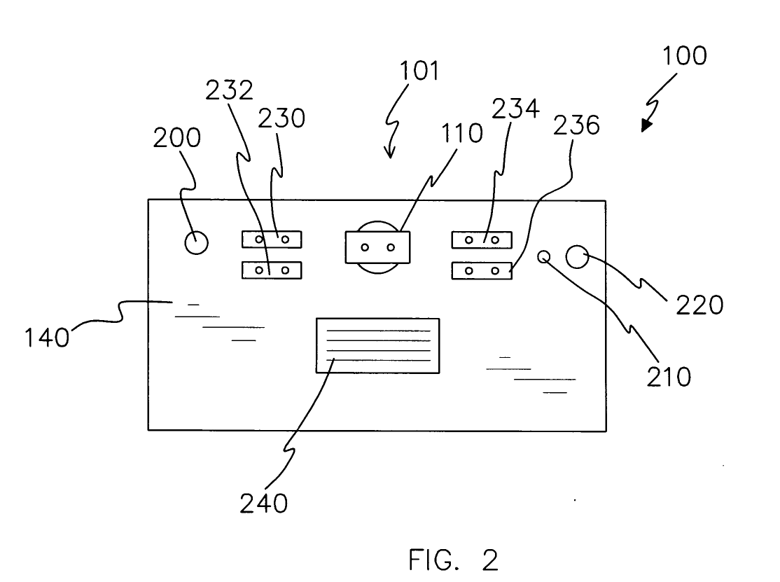

### DETAILED DESCRIPTION OF THE INVENTION

For the purposes of promoting an understanding of the principles of the invention, reference will now be made to the exemplary embodiments illustrated in the drawings, and specific language will be used to describe the same. It will nevertheless be understood that no limitation of the scope of the invention is thereby intended. Any alterations and further modifications of the inventive features illustrated herein, and any additional applications of the principles of the invention as illustrated herein, which would occur to one skilled in the relevant art and having possession of this disclosure, are to be considered within the scope of the invention.

Reference throughout this specification to “one embodiment,” “an embodiment,” or similar language means that a particular feature, structure, or characteristic described in connection with the embodiment is included in at least one embodiment of the present invention. Thus, appearances of the phrases “one embodiment,” “an embodiment,” and similar language throughout this specification may, but do not necessarily, all refer to the same embodiment, different embodiments, or component parts of the same or different illustrated invention. Additionally, reference to the wording “an embodiment,” or the like, for two or more features, elements, etc. does not mean that the features are related, dissimilar, the same, etc. The use of the term “an embodiment,” or similar wording, is merely a convenient phrase to indicate optional features, which may or may not be part of the invention as claimed.

Each statement of an embodiment is to be considered independent of any other statement of an embodiment despite any use of similar or identical language characterizing each embodiment. Therefore, where one embodiment is identified as “another embodiment,” the identified embodiment is independent of any other embodiments characterized by the language “another embodiment.” The independent embodiments are considered to be able to be combined in whole or in part one with another as the claims and/or art may direct, either directly or indirectly, implicitly or explicitly.

Finally, the fact that the wording “an embodiment,” or the like, does not appear at the beginning of every sentence in the specification, such as is the practice of some practitioners, is merely a convenience for the reader's clarity. However, it is the intention of this application to incorporate by reference the phrasing “an embodiment,” and the like, at the beginning of every sentence herein where logically possible and appropriate.

Many of the functional units described in this specification have been labeled as modules, in order to more particularly emphasize their implementation independence. For example, a module may be implemented as a hardware circuit comprising custom VLSI circuits or gate arrays, off-the-shelf semiconductors such as logic chips, transistors, or other discrete components. A module may also be implemented in programmable hardware devices such as field programmable gate arrays, programmable array logic, programmable logic devices or the like.

Modules may also be implemented in software for execution by various types of processors. An identified module of executable code may, for instance, comprise one or more physical or logical blocks of computer instructions which may, for instance, be organized as an object, procedure, or function. Nevertheless, the executables of an identified module need not be physically located together, but may comprise disparate instructions stored in different locations which, when joined logically together, comprise the module and achieve the stated purpose for the module.

Indeed, a module of executable code may be a single instruction, or many instructions, and may even be distributed over several different code segments, among different programs, and across several memory devices. Similarly, operational data may be identified and illustrated herein within modules, and may be embodied in any suitable form and organized within any suitable type of data structure. The operational data may be collected as a single data set, or may be distributed over different locations including over different storage devices, and may exist, at least partially, merely as electronic signals on a system or network.

Looking to the Figures, there is shown a portable electronics testing device 100 according to one embodiment of the invention. In particular, there is shown a portable electronics testing device 100 for use in testing automotive electronics, such as but not limited to players of CDs, DVDs, and MP3s; navigation equipment, and radar detectors. There is shown a housing 140, including: a shell 140; a handle 120, coupled to the shell 140, configured to facilitate lifting the housing 140; and a wheel 160 and/or 162 coupled to the shell 140 and configured to facilitate travel of the housing 140; and an electronics module 101 coupled to the housing 140, configured to test an electronic device (not shown).

The electronics module 101 shown includes a speaker module 130 configured to produce audio; a speaker connection module 230 coupled to the speaker module 130 and configured to provide an interface for driving the speaker module 130; a power module 150 configured to provide electrical power; and a receiver module 220 configured to receive radio frequency information. The receiver module 220 shown is an antennae for receiving radio frequency information such as but not limited to a radio broadcast. There is also shown a antennae lead 210 coupled to the antennae 220.

In the illustrated example, speaker module 130 comprises a set of four speakers 130,132,134, and 136 each speaker 130 independently interfaceable through the speaker connection module(s) 230, 232, 234, and 236. In the illustrated example, the speakers and speaker connection modules correspond to a left front (130 and 230), a left rear (132 and 232), a right front (134 and 234), and a right rear (136 and 236) speaker. There is also shown a wire color code label 240 providing instructions and reference material for a user. There is further illustrated an extendable handle 120 extendably coupled to the housing 140. More, there is shown a cigarette lighter/12 volt output 200 electrically coupled to the power module 150 and extending through the housing 140 such that the 12 volt output 200 may be accessible.

In operation, a user may couple and/or attach one or more electronic devices to the portable electronics testing device 100. The portable electronics testing device 100 may be easily rolled to a convenient location, such as near a vehicle in a garage. The portable electronics testing device 100 may also be brought to a purchase location such as a booth where a consumer may use the portable electronics testing device 100 to test a product such as but not limited to a speaker or a CD player before purchasing the product. The portable electronics testing device 100 includes all components and connections necessary to test such devices and to evaluate a wide range of functionality. Accordingly, the portable electronics testing device 100 may be used to more quickly, accurately, and/or easily test electronics devices.

It is understood that the above-described preferred embodiments are only illustrative of the application of the principles of the present invention. The present invention may be embodied in other specific forms without departing from its spirit or essential characteristics. The described embodiment is to be considered in all respects only as illustrative and not restrictive. The scope of the invention is, therefore, indicated by the appended claim rather than by the foregoing description. All changes which come within the meaning and range of equivalency of the claims are to be embraced within their scope.

Thus, while the present invention has been fully described above with particularity and detail in connection with what is presently deemed to be the most practical and preferred embodiment of the invention, it will be apparent to those of ordinary skill in the art that numerous modifications, including, but not limited to, variations in size, materials, shape, form, function and manner of operation, assembly and use may be made, without departing from the principles and concepts of the invention as set forth in the claims.

What is claimed is:

1. A portable electronics testing device for use in testing automotive electronics, comprising:
a housing, including:
a shell;
a handle, coupled to the shell, configured to facilitate lifting the housing; and
a wheel coupled to the shell and configured to facilitate travel of the housing; and an electronics module coupled to the housing, configured to test an electronic device, and including:
a speaker module configured to produce audio;
a speaker connection module coupled to the speaker module and configured to provide an interface for driving the speaker module;
a power module configured to provide electrical power; and
a receiver module configured to receive radio frequency information.

2. The portable electronics module of claim 1, wherein the speaker module comprises a set of four speakers each speaker independently interfaceable through the speaker connection module.

3. The portable electronics module of claim 2, wherein the housing further comprises an extendable handle.

4. The portable electronics module of claim 3, wherein the housing further comprises a wire color code label.

5. A portable electronics testing device for use in testing automotive electronics, consisting essentially of:
a housing, including:
a shell;
a handle, coupled to the shell, configured to facilitate lifting the housing; and
a wheel coupled to the shell and configured to facilitate travel of the housing; and an electronics module coupled to the housing, configured to test an electronic device, and including:
a speaker module configured to produce audio;
a speaker connection module coupled to the speaker module and configured to provide an interface for driving the speaker module;
a power module configured to provide electrical power; and
a receiver module configured to receive radio frequency information.

6. The portable electronics module of claim 5, wherein the speaker module comprises a set of four speakers each speaker independently interfaceable through the speaker connection module.

7. The portable electronics module of claim 6, wherein the housing further comprises an extendable handle.

8. The portable electronics module of claim 7, wherein the housing further comprises a wire color code label.
